(19) United States
(12) Patent Application Publication
(10) Pub. No.: US 2011/0215367 A1
(43) Pub. Date: Sep. 8, 2011

(54) ORGANIC ELECTROLUMINESCENCE ELEMENT AND LIGHT-EMITTING APPARATUS HAVING THE SAME

(75) Inventors: Takayuki Ito, Mobara-shi (JP); Naoyuki Ito, Yokohama-shi (JP); Shoji Sudo, Kawasaki-shi (JP); Takayuki Sumida, Mobara-shi (JP)

(73) Assignee: CANON KABUSHIKI KAISHA, Tokyo (JP)

(21) Appl. No.: 13/038,233

(22) Filed: Mar. 1, 2011

(30) Foreign Application Priority Data
Mar. 2, 2010 (JP) 2010-045541
Jan. 25, 2011 (JP) 2011-013277

(51) Int. Cl. H01L 51/52

(52) U.S. Cl. 257/99; 257/E51.019

(57) ABSTRACT

An organic EL element has a substrate, a first electrode, an organic compound layer, and a second electrode. The second electrode has a base layer and a metal layer, and light generated in this organic EL element is transmitted through the second electrode. The base layer is closer to the substrate than the metal layer and is a mixed layer containing lithium, oxygen, and magnesium, whereas the metal layer contains silver and has a thickness in the range of 5.0 to 20 nm, inclusive.

### BACKGROUND OF THE INVENTION

1. Field of the Invention

The present invention relates to an organic electroluminescence (EL) element that offers a high luminous efficiency despite the use of a silver thin film as one of its electrodes. The present invention also relates to a light-emitting apparatus having such an organic EL element.

2. Description of the Related Art

Organic EL elements have two electrodes and an organic compound layer sandwiched between these two electrodes. The organic compound layer contains a light-emitting layer, and this light-emitting layer generates light. Then, light is emitted through either one of the two electrodes (hereinafter also referred to as a light-transmitting electrode). Some researchers have proposed using a thin film made of silver as the light-transmitting electrode because silver thin films are highly electroconductive and highly transmissive to visible light.

In general, however, silver thin films having a thickness equal to or smaller than 20 nm are not continuous films. Discontinuous films are less electroconductive than continuous ones and less transmissive to visible light because local surface plasmon resonance induces the absorption of visible light. As a solution to this problem encountered with the use of silver thin films, Japanese Patent Laid-Open No. 2008-171637 has disclosed a kind of organic EL element. In this organic EL element, a transparent electroconductive laminate constituted by a non-silver metal base layer and a silver or silver alloy thin film is used as one of the electrodes, and the material of the base layer can be selected from the group consisting of gold, aluminum, copper, indium, tin, and zinc.

After carefully reviewing the constitution of this transparent electroconductive laminate, however, the present inventors concluded that this constitution could not sufficiently reduce the absorption of light induced by local surface plasmon resonance.

### SUMMARY OF THE INVENTION

To solve this problem, the present invention provides an organic EL element that offers a high luminous efficiency despite the use of a silver thin film as one of its electrodes.

An organic EL element according to the present invention has a substrate, a first electrode, a second electrode, and an organic compound layer. The organic compound layer is placed between the first electrode and second electrode and contains a light-emitting layer. The second electrode has a base layer and a metal layer formed on this base layer, and light generated in this organic EL element is transmitted through this second electrode. The base layer is closer to the substrate than the metal layer and is a mixed layer containing lithium, oxygen, and magnesium, whereas the metal layer contains silver and has a thickness in the range of 5.0 to 20 nm, inclusive.

Constituted as above, this organic EL element can be operated even at a low voltage and offer a high luminous efficiency despite the use of a silver thin film as one of its electrodes.

Further features of the present invention will become apparent from the following description of exemplary embodiments with reference to the attached drawings.

### BRIEF DESCRIPTION OF THE DRAWINGS

FIGS. 1A and 1B illustrate an organic EL element according to the invention and a light-emitting apparatus having it, respectively.

FIG. 2 illustrates plots of wavelength versus transmittance obtained for Reference Example 1 and Comparative Examples 1 to 4.

FIGS. 3A to 3C illustrate plots of wavelength versus transmittance obtained for Reference Examples 2 to 4.

FIGS. 4A to 4D illustrate plots of wavelength versus transmittance obtained for Reference Examples 5 to 8.

FIG. 5 illustrates electron-injection profiles obtained for electron-only elements (i.e., elements allowing only electrons to flow therethrough) according to Reference Example 9 and Comparative Example 5.

### DESCRIPTION OF THE EMBODIMENTS

The following details some embodiments of the present invention with reference to drawings.

### First Embodiment

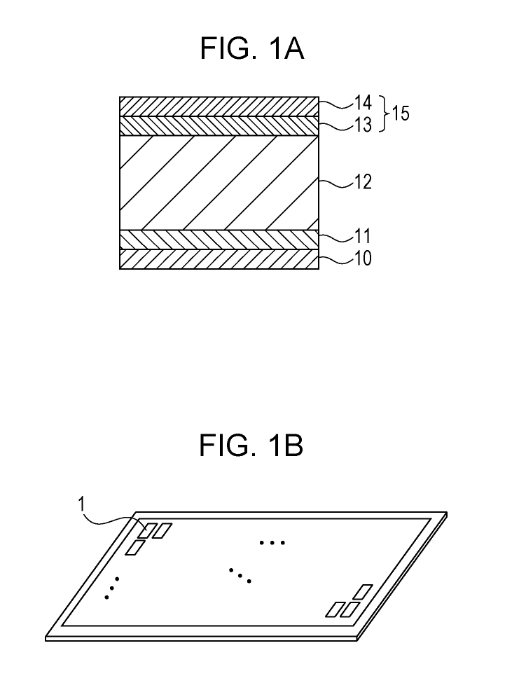

FIG. 1A is a schematic cross-sectional view of an organic EL element according to the present invention. As can be seen from the drawing, this organic EL element has a substrate 10, a first electrode 11, an organic compound layer 12, and a second electrode 15. The organic compound layer 12 is placed between the first electrode 11 and the second electrode 15 and contains a light-emitting layer. This organic EL element has the “top-emission” structure, in which the electrode more distant from the substrate 10 than the other one, namely, the second electrode 15, transmits light therethrough. The second electrode 15 has a base layer 13 and a metal layer 14 formed on this base layer 13. The base layer 13 is closer to the substrate 10 than the metal layer 14 and is a mixed layer containing lithium (Li), oxygen (O), and magnesium (Mg), whereas the metal layer 14 contains silver (Ag) and has a thickness in the range of 5.0 to 20 nm, inclusive. This constitution is advantageous in the following ways: Reduced local surface plasmon resonance on the metal layer 14 and accordingly reduced absorption of visible light allow the organic EL element to keep a sufficiently high transmittance; The base layer 13 effectively mediates the electron injection from the metal layer 14 into the organic compound layer 12, enabling the organic EL element to be operated even at a low voltage.

Although not illustrated in the drawings, organic EL elements having the “bottom-emission” structure, in which the substrate itself transmits light therethrough, can also benefit from the present invention. If the bottom-emission structure is used, the second electrode is formed on the substrate, and then the organic compound layer and the first electrode are formed. As in the constitution described above, the second electrode has a base layer and a metal layer, and the base layer is closer to the substrate than the metal layer.

Turning back to the description of the first embodiment of the present invention, the metal layer 14 is a thin film made of pure silver or a silver alloy (hereinafter collectively referred to as a silver thin film). The content ratio of silver in this metal layer 14 is preferably equal to or higher than 90% by volume. For example, the silver thin film contains, in addition to silver, small amounts (a total of <10% by volume) of palladium (Pd), copper (Cu), magnesium (Mg), gold (Au), and some other appropriate metals. The thickness is preferably in the range of 5.0 to 20 nm, inclusive, and more preferably in the range of 8.0 to 12 nm, inclusive. With the metal layer 14 having a thickness falling within any of these ranges, the organic EL element can be highly electroconductive and highly transmissive to visible light (wavelength: 400 to 780 nm).

On the other hand, the base layer 13 is a hybrid (mixed) film containing lithium oxide (Li₂O) and magnesium (Mg). For magnesium, the content ratio is preferably in the range of 10% to 50% by volume, inclusive, and more preferably in the range of 10% to 30% by volume, inclusive, relative to the total volume of the base layer 13.

When the density ratio of Li₂O to Mg is defined as ρ₁, the volume content ratio of Mg in the base layer 13 as X (percent by volume), and the weight content ratio of Mg in the base layer 13 as Y (percent by weight), Y is expressed as follows: Y=100/{1+ρ₁(100/X−1)}. The density is 2.013 g/cm³ for Li₂O and 1.738 g/cm³ for Mg; therefore, ρ₁ is 1.158. If X is 10, then Y is 8.75, and if X is 50, then Y is 46.33. Thus, the range of the content ratio of Mg in the base layer 13 from 10% to 50% by volume, inclusive, corresponds to 8.8% to 46.3% by weight, inclusive, and the range of the content ratio of Mg in the base layer 13 from 10% to 30% by volume, inclusive, corresponds to 8.8% to 27.0% by weight. For the weight content ratios, the place of the last significant figure is one decimal place.

When the molar ratio of Li₂O to Mg is defined as ρ₂, and the molar content ratio of Mg in the base layer 13 is defined as Z (percent by number of moles), Z is expressed as follows: Z=100/{1+(ρ₁/ρ₂) (100/X−1)} (for ρ₁ and X, see above). The molecular weight is 29.88 for Li₂O and 24.31 for Mg; therefore, ρ₂ is 1.229, and ρ₁/ρ₂ is 0.9423. If X is 10, then Z is 10.55, and if X is 50, then Z is 51.49. Thus, the range of the content ratio of Mg in the base layer 13 from 10% to 50% by volume, inclusive, corresponds to 10.6% to 51.5% by number of moles, inclusive, and the range of the content ratio of Mg in the base layer 13 from 10% to 30% by volume, inclusive, corresponds to 10.6% to 31.3% by number of moles. For the molar content ratios, the place of the last significant figure is one decimal place.

Accordingly, the conditions for the content ratio of silver in the metal layer 14 can be rewritten as follows: The content ratio of silver in the metal layer 14 is preferably equal to or higher than 83.0% by weight and the most preferably equal to or higher than 90.0% by weight. Likewise, the content ratio of silver in the metal layer 14 is preferably equal to or higher than 92.4% by number of moles and the most preferably equal to or higher than 95.0% by number of moles.

The thickness of the base layer is in the range of 2.0 to 20 nm, inclusive, preferably in the range of 4.0 to 16 nm, inclusive, and more preferably in the range of 6.0 to 10 nm, inclusive.

With the base layer 13 constituted as above, the second electrode 15 is more transmissive than only with the silver thin film to light having a wavelength longer than the blue-light wavelength (450 nm). The mechanism underlying this protective effect of the base layer 13 on the transmittance of the second electrode 15 is unclear; however, the following probably explains the effect.

Magnesium needs a smaller free energy for oxide formation than lithium (Li). In the Li₂O—Mg hybrid film, thus, some portion of Li₂O is chemically reduced to release lithium atoms, and these lithium atoms accumulate at the exposed surface of the base layer 13, or the surface onto which the metal layer 14 is formed. In general, lithium atoms are likely to make bonds with silver atoms. Thus, the lithium atoms accumulating at the surface of the base layer 13 act as cores around which the material of the metal layer 14 can spread. Growing around the cores within the surface of the base layer 13, the coatings formed from the material of the metal layer 14 evenly cover the whole surface of the base layer 13, thereby forming a single continuous film. As a result of the continuity of the metal layer 14 achieved in this way, local surface plasmon resonance is reduced on the metal layer 14, and accordingly the metal layer 14 is relatively unlikely to absorb light despite its small thickness.

The release of lithium atoms offers another advantage, a weakened barrier on the organic compound layer 12 against electron injection, thereby facilitating the electron injection from the metal layer 14 into the organic compound layer 12. Furthermore, magnesium atoms mixed with Li₂O molecules provide electroconductive paths; as a result, the organic EL element can be operated even at a low voltage despite the use of Li₂O, a highly insulating material.

Incidentally, magnesium may be replaced with any alkaline-earth metal such as calcium (Ca) or any alkali metal such as cesium (Cs). These kinds of metals probably have the same effect as magnesium.

In the base layer 13, magnesium may have a certain concentration gradient. For example, if the concentration (percent by volume) of magnesium in the base layer 13 becomes higher as the measuring point approaches the metal layer 14, more lithium atoms can accumulate at the surface of the base layer 13 than at any deeper levels.

Then, the following describes other essential components of this organic EL element. The substrate 10 may be a glass substrate, a plastic substrate, or some other appropriate dielectric substrate. Furthermore, the substrate 10 may be a laminate constituted by a base substrate, a switching element formed on this base substrate, and an insulating layer formed on this switching element. An example of the switching element is a thin-film transistor (TFT); it serves as a switch for changing the intensity of the light emitted from the organic EL element.

The first electrode 11 can be a highly reflective electrode, for example, a metal film that has a thickness in the range of 50 to 300 nm, inclusive, and is made of aluminum (Al), silver (Ag), molybdenum (Mo), tungsten (W), nickel (Ni), chromium (Cr), or an alloy of some or all of these metals. The method for forming this metal film may be any of known appropriate methods such as vapor deposition or sputtering. The first electrode 11 may further have a transparent and electroconductive oxide layer on its light-transmitting side. This transparent and electroconductive oxide layer is made of tin oxide (SnO₂), indium oxide (In₂O₃), indium tin oxide (ITO), indium zinc oxide (IZO), or some other transparent and electroconductive oxide, and its thickness is preferably in the range of 5.0 to 100 nm, inclusive. Note that the term transparent here means that the electroconductive oxide layer has a transmittance to visible light equal to or higher than 40%.

The organic compound layer 12 optionally contains, in addition to the light-emitting layer, functional layers such as a hole-injection layer, a hole-transport layer, a hole-blocking layer, an electron-injection layer, an electron-transport layer, and an electron-blocking layer. These functional layers are individually made of any known appropriate material and stacked in an appropriate order.

The second electrode 15 may have additional layers formed thereon. Examples of additional layers formed on the second electrode 15 include the transparent and electroconductive oxide layer mentioned above, an organic compound coating having a high refractive index, a protective layer made of silicon nitride (SiN), and so forth.

### Second Embodiment

The following details another embodiment of the present invention. As illustrated in FIG. 1B, this embodiment is represented by a light-emitting apparatus.

This light-emitting apparatus has several pixels 1 and a mechanism for controlling the intensity of the light emitted from the pixels 1, such as a TFT, and the pixels 1 are each provided with an organic EL element according to the invention.

This light-emitting apparatus can also be used as a display apparatus. This display apparatus has several pixel units arranged in a matrix, and each pixel unit can be constituted by several pixels of different colors, for example, a red pixel, a green pixel, and a blue pixel. The red pixel has an organic EL element that emits red light. When a light-emitting apparatus according to the present invention has a red pixel, a green pixel, and a blue pixel, some or all of the pixels 1 contained in this light-emitting apparatus may be each provided with an organic EL element according to the present invention.

The term pixel here represents an independent and minimum unit the intensity of the light emitted from which can be controlled, and the term pixel unit a minimum unit that is constituted by two or more pixels of different colors and emits light in an intended color as a mixture of the colors of the individual pixels.

In this embodiment, organic EL elements according to the present invention may be used in some or all of the pixels 1. In other words, light-emitting apparatuses according to this embodiment may have two types of organic EL elements, ones according to the present invention and known ones. Such light-emitting apparatuses allow for the control of the proportion between the two types of organic EL elements and thus can have any intended light-emission characteristics.

In these light-emitting apparatuses having the two types of organic EL elements, organic EL elements according to the present invention and known ones may be arranged regularly or randomly.

In addition, the pixels 1 may each have a light-transmission promoter, an element that improves the efficiency of light transmission through the pixels 1. This light-transmission promoter may be used in all of the pixels 1 or in some selected ones.

Light-emitting apparatuses according to the present invention can be used in a wide variety of applications, including illuminators, printer heads, exposure apparatuses, display backlights, and so forth. If a light-emitting apparatus according to the present invention is used as a display apparatus as mentioned above, examples of applications include television systems, personal computer screens, the back screen of image-pickup apparatuses, cell-phone screens, portable gaming console screens, portable audio player screens, PDA (personal digital assistant) screens, car navigation system screens, and so forth.

### EXAMPLES

### Reference Example 1

First, transmittance was measured in some test specimens. Each test specimen was prepared as the second electrode for organic EL elements according to the present invention, namely, a laminate of a base layer and a metal layer, placed on a substrate.

Reference Example 1 included two test specimens. These two test specimens were both constituted by a Li₂O—Mg hybrid film (the base layer) and a silver thin film (the metal layer) stacked on a glass substrate, but different from each other in the content ratio of magnesium (percent by volume) in the base layer.

The procedure used to prepare these test specimens was as follows. First, Li₂O and magnesium were co-deposited on two glass substrates by vapor deposition under the following two sets of conditions for two hybrid films of different compositions: total deposition speed of Li₂O and magnesium: 1.0 Å/s for both hybrid films; content ratio of magnesium in the base layer: 10% by volume for one, 50% by volume for the other; target thickness: 10 nm for both. More specifically, for the hybrid film containing magnesium at 10% by volume in the base layer, the deposition speed for Li₂O was set at 0.9 Å/s and that for magnesium at 0.1 Å/s. The degree of vacuum in the vapor deposition chamber used was maintained in the range of 2×10⁻⁵ to 8×10⁻⁵ Pa during the formation of these hybrid films. Then, a silver thin film was formed on each obtained structure to a thickness of 10 nm with the film formation speed set at 0.3 Å/s. The products were then placed in a nitrogen atmosphere and then individually covered with a sheet of glass and sealed using an epoxy resin adhesive agent; in this way, the silver thin films were protected from air oxidation.

### Comparative Example 1

A test specimen was prepared by the same procedure as in Reference Example 1 except that the base layer was omitted. In other words, only a silver thin film was formed on a glass substrate to a thickness of 10 nm.

### Comparative Example 2

A test specimen was prepared by the same procedure as in Reference Example 1 except that the base layer contained no magnesium. In other words, the base layer was a Li₂O film formed on a glass substrate to a thickness of 10 nm with the film formation speed set at 1.0 Å/s.

### Comparative Example 3

A test specimen was prepared by the same procedure as in Reference Example 1 except that the base layer was constituted by two separate films. More specifically, a Li₂O film was formed on a glass substrate to a thickness of 10 nm with the film formation speed set at 1.0 Å/s, and then a magnesium film was formed on this Li₂O film to a thickness of 1.0 nm with the film formation speed set at 0.5 Å/s.

### Comparative Example 4

A test specimen was prepared by the same procedure as in Reference Example 1 except that the base layer was an aluminum (Al) film. More specifically, an aluminum film was formed on a glass substrate to a thickness of 2.0 nm with the film formation speed at 0.5 Å/s.

### Measurement of Transmittance

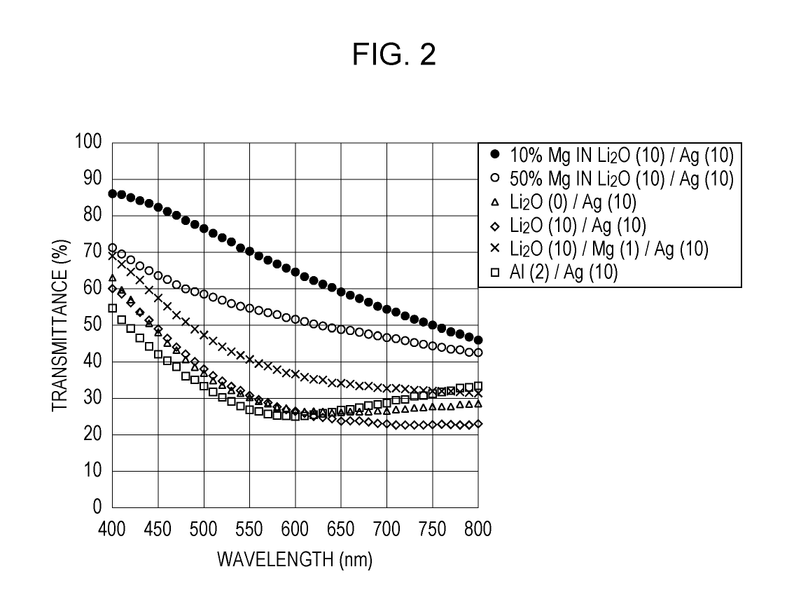

The obtained test specimens were subjected to the measurement of transmittance. The analyzer used was Ubest V-560 spectrophotometer (JASCO Corporation), and the blank used was a glass substrate covered only with a sheet of glass and sealed. The glass substrate was from the same lot number as those used in Reference Example 1 and Comparative Examples 1 to 4. FIG. 2 illustrates plots of wavelength versus transmittance obtained for Reference Example 1 and Comparative Examples 1 to 4.

As can be seen from FIG. 2, the test specimens of Reference Example 1 showed better transmittance values than those of Comparative Examples 1 to 4.

### Reference Example 2

Then, transmittance was measured in another set of test specimens. These test specimens further contained the organic compound layer; each test specimen was prepared as the second electrode for organic EL elements according to the present invention, namely, a laminate of a base layer and a metal layer, placed on an organic compound layer formed on a substrate.

Reference Example 2 included a series of five test specimens and another test specimen. The five test specimens were all constituted by an organic compound film (the organic compound layer), a Li₂O—Mg hybrid film (the base layer), and a silver thin film (the metal layer) stacked on a glass substrate, but different from each other in the content ratio of magnesium (percent by volume) in the base layer. The remaining one had no base layer; it was constituted by an organic compound layer and a silver thin film stacked on a glass substrate.

The procedure used to prepare these test specimens was as follows. First, an organic compound film was formed from Compound 1 (presented below) on each of six glass substrates to a thickness of 20 nm with the film formation speed set at 1.0 Å/s. Then, a Li₂O—Mg hybrid film was formed on five of the glass substrates, excluding one for the test specimen having no base layer, with the content ratio of magnesium in the base layer set at 0%, 10%, 30%, 50%, or 70% by volume. The target thickness of the hybrid film was 2.0 nm for all of these five test specimens, and the deposition speeds of Li₂O and magnesium were set in the same way as in Reference Example 1. Then, all the obtained structures including the one having no base layer were each coated with a silver thin film. This silver thin film was formed to a thickness of 10 nm with the film formation speed set at 0.3 Å/s. The products were then placed in a nitrogen atmosphere and then individually covered with a sheet of glass and sealed using an epoxy resin adhesive agent.

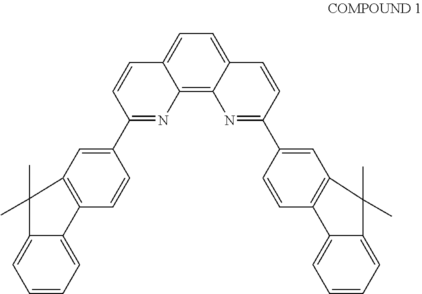

### Reference Example 3

Six test specimens were prepared by the same procedure and under the same conditions including the content ratio of Mg in the base layer as in Reference Example 2 except that the target thickness of the base layer was set at 4.0 nm.

### Reference Example 4

Six test specimens were prepared by the same procedure and under the same conditions including the content ratio of Mg in the base layer as in Reference Example 2 except that the target thickness of the base layer was set at 6.0 nm.

### Reference Example 5

Six test specimens were prepared by the same procedure and under the same conditions including the content ratio of Mg in the base layer as in Reference Example 2 except that the target thickness of the base layer was set at 8.0 nm.

### Reference Example 6

Six test specimens were prepared by the same procedure and under the same conditions including the content ratio of Mg in the base layer as in Reference Example 2 except that the target thickness of the base layer was set at 10 nm.

### Reference Example 7

Six test specimens were prepared by the same procedure and under the same conditions including the content ratio of Mg in the base layer as in Reference Example 2 except that the target thickness of the base layer was set at 16 nm.

### Reference Example 8

Six test specimens were prepared by the same procedure and under the same conditions including the content ratio of Mg in the base layer as in Reference Example 2 except that the target thickness of the base layer was set at 20 nm.

### Measurement of Transmittance

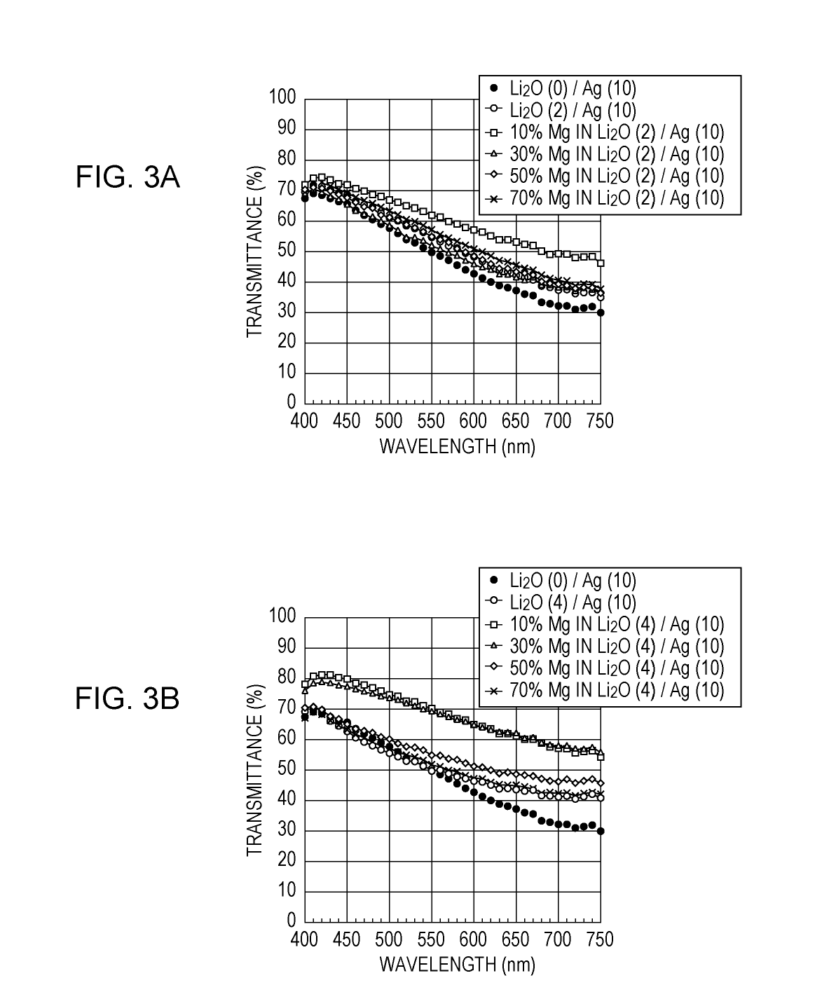

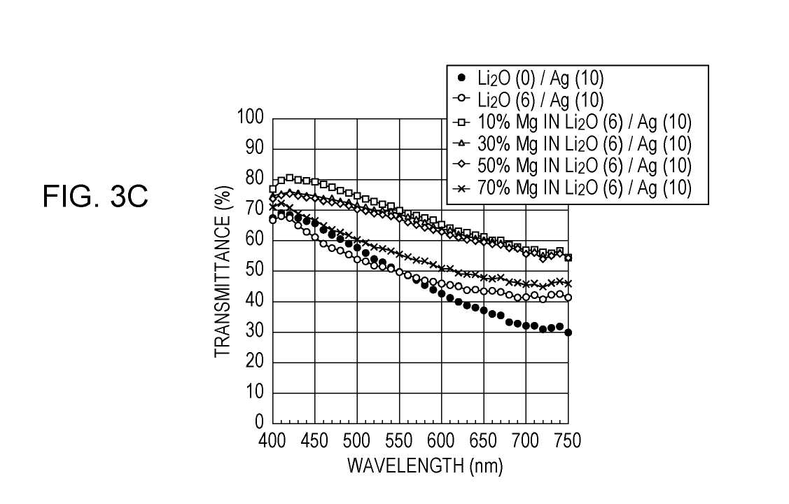

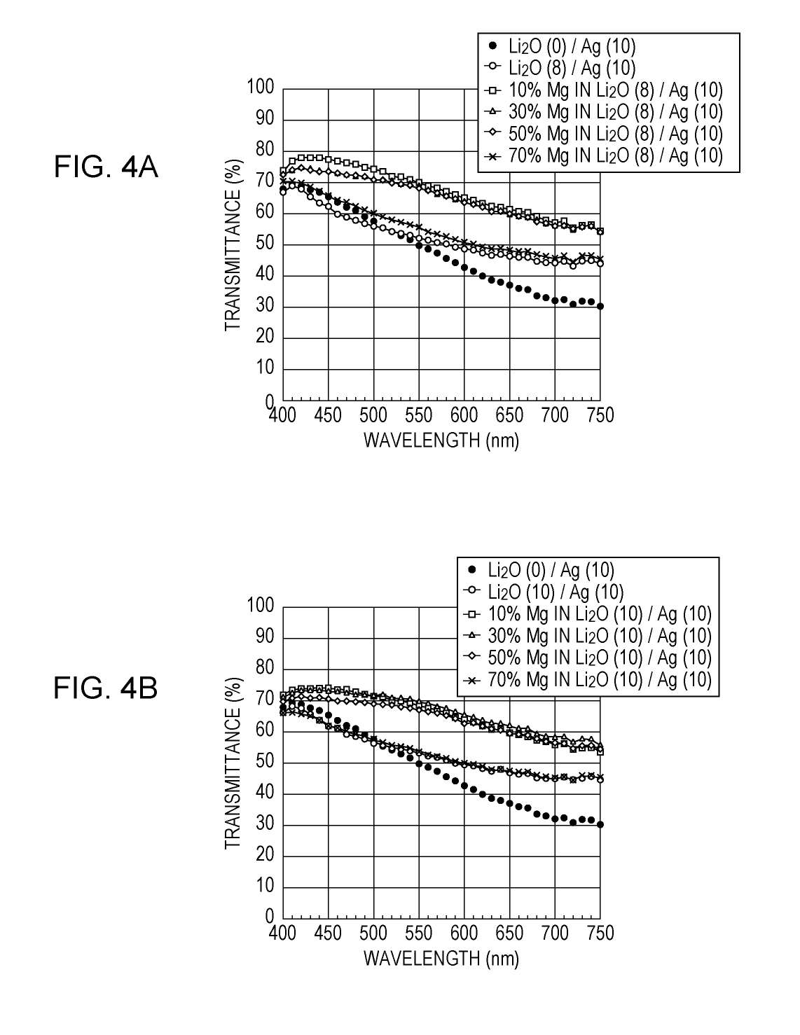

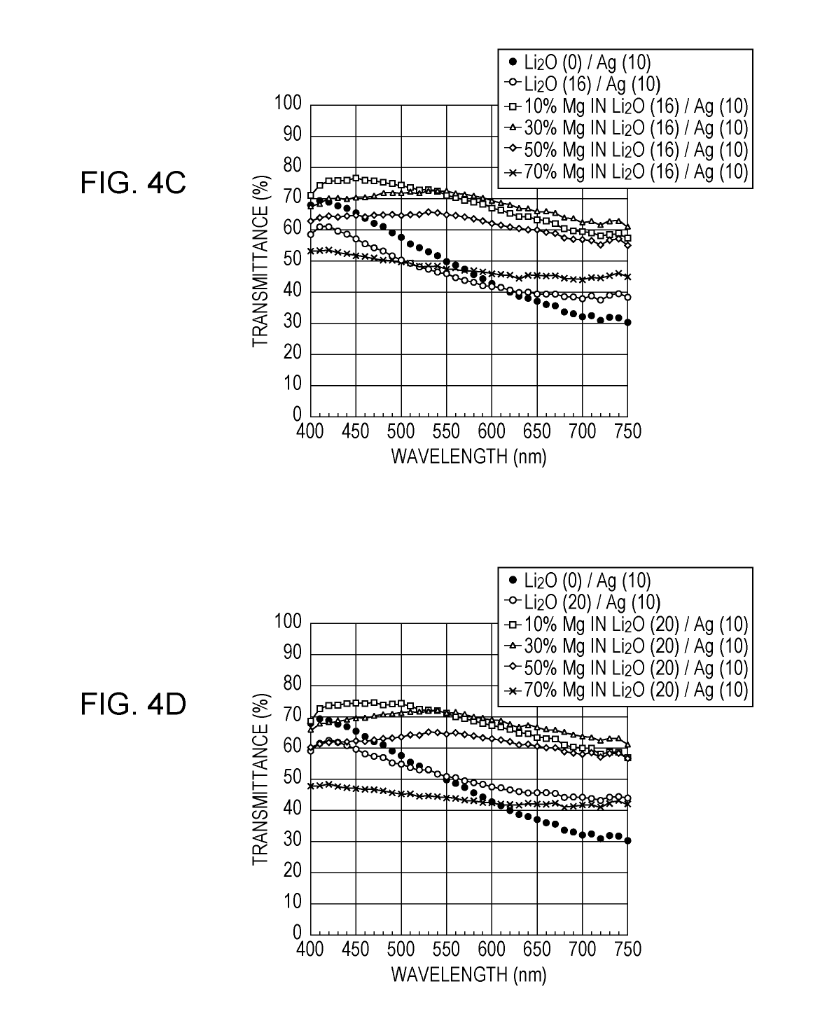

The obtained test specimens were subjected to the measurement of transmittance in the same way as those of Reference Example 1 and Comparative Examples 1 to 4. FIGS. 3A to 3C and 4A to 4D illustrate plots of wavelength versus transmittance obtained for Reference Examples 2 to 4 and 5 to 8, respectively.

FIGS. 3A to 3C show the dependence of the transmittance of each test specimen (a metal layer with or without a base layer) on the content ratio of magnesium (percent by volume) in the base layer for Reference Examples 2 to 4, and FIGS. 4A to 4D show the same information for Reference Examples 5 to 8. In the reference examples in which the base layer had a thickness of 4.0 nm, 6.0 nm, 8.0 nm, 10 nm, or 16 nm, the test specimens having the base layer were more transmissive than that with no base layer to light having a wavelength longer than the blue-light wavelength (450 nm) when the content ratio of magnesium in the base layer was 10%, 30%, or 50% by volume. Insofar as the reference examples in which the base layer had a thickness of 4.0 nm, 6.0 nm, 8.0 nm, or 10 nm are concerned, the test specimens having the base layer were more transmissive than that with no base layer even to light having a wavelength shorter than the blue-light wavelength (450 nm) when the content ratio of magnesium in the base layer was 10%, 30%, or 50% by volume. Furthermore, insofar as the reference examples in which the base layer had a thickness of 6.0 nm, 8.0 nm, or 10 nm are concerned, the test specimens having the base layer were highly transmissive to light in the entire visible range when the content ratio of magnesium in the base layer was 10%, 30%, or 50% by volume.

Note that the test specimens in which the content ratio of magnesium in the base layer was 70% by volume were insufficiently transmissive. This is probably because highly concentrated magnesium atoms absorb a considerable amount of light.

### Reference Example 9

Then, the electron-injection profile was determined in yet another set of test specimens. Each test specimen was prepared as the second electrode for organic EL elements according to the present invention, namely, a laminate of a base layer and a metal layer, placed on an organic compound layer formed on a substrate.

Reference Example 9 included two test specimens. These two test specimens were both constituted by an organic compound film (the organic compound layer), a Li₂O—Mg hybrid film (the base layer), and a silver thin film (the metal layer) stacked on a patterned ITO-glass substrate, but different from each other in the content ratio of magnesium (percent by volume) in the base layer.

The procedure used to prepare these test specimens was as follows. First, an organic compound film was formed from Compound 1 (presented above) on each of two patterned ITO-glass substrates to a thickness of 50 nm with the film formation speed set at 1.0 Å/s. Then, a Li₂O—Mg hybrid film was formed on each obtained structure under the following two sets of conditions for two hybrid films of different compositions: total deposition speed of Li₂O and magnesium: 1.0 Å/s for both hybrid films; content ratio of magnesium in the base layer: 10% by volume for one, 50% by volume for the other; target thickness: 4.0 nm for both. Then, a silver thin film was formed on each product to a thickness of 10 nm with the film formation speed set at 0.3 Å/s; in this way, two electron-only elements were obtained. The obtained electron-only elements were placed in a glove box filled with nitrogen and then individually covered with a sheet of glass containing a desiccating agent and sealed using an epoxy resin adhesive agent.

### Comparative Example 5

Three test specimens were prepared by the same procedure as in Reference Example 9 except that the base layer contained no magnesium and had different thicknesses. In other words, the base layer was a Li₂O film formed on a patterned ITO-glass substrate to a thickness of 2.0 nm, 4.0 nm, or 10 nm with the film formation speed set at 1.0 Å/s.

### Determination of Electron-Injection Profile

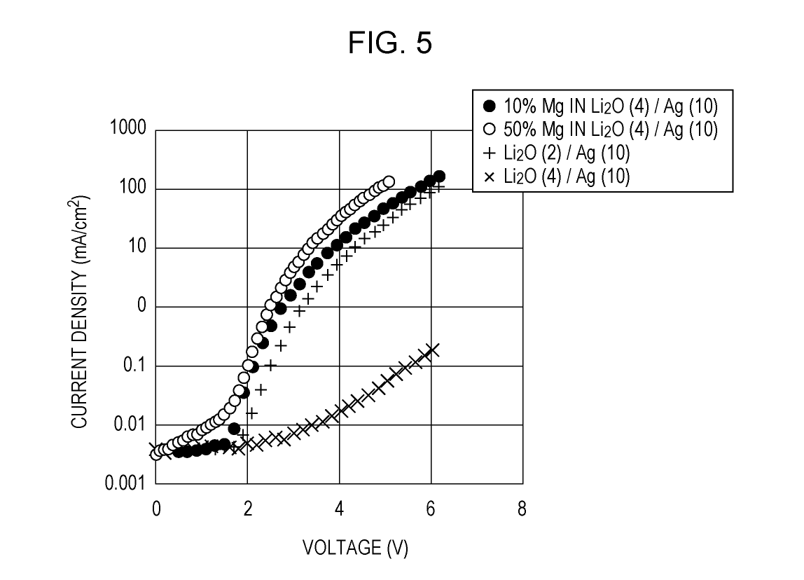

The obtained electron-only elements were energized with the substrate (ITO) as the anode and the metal layer (silver) as the cathode, and the generated current was measured. FIG. 5 illustrates plots of voltage versus current density obtained for Reference Example 9 and Comparative Example 5. As can be seen from these plots, the electron-only elements of Reference Example 9 both showed a favorable electron-injection profile and could be operated at a lower voltage than those of Comparative Example 5, in which the base layer was a Li₂O film containing no magnesium. This is probably because magnesium chemically reduced some portion of Li₂O to make lithium atoms released, thereby weakening the barrier against electron injection existing between the base layer and the organic compound layer. Note that the electron-only element in which the base layer was a Li₂O film having a thickness of 4.0 nm needed a higher voltage to operate than the others. Furthermore, although not shown in FIG. 5, no current was detected in the electron-only element in which the base layer was a Li₂O film having a thickness of 10 nm. These results also agree with the assumption that magnesium atoms mixed with Li₂O molecules provide electroconductive paths.

### Example 1

The following details an organic EL element according to the present invention. This organic EL element is a top-emission organic EL element emitting blue light and has a constitution like that illustrated in FIG. 1.

The procedure used to fabricate this organic EL element was as follows. First, a glass substrate 10 was coated with a first electrode 11. This first electrode 11 was a laminate of an aluminum alloy film and an indium tin oxide (IZO) film. The aluminum alloy film was first formed by sputtering from an alloy of aluminum (Al) and neodymium (Nd) to a thickness of 100 nm, and the IZO film was then formed by sputtering to a thickness of 40 nm.

Then, an organic compound layer 12 was formed. Specific processes for the formation of this organic compound layer 12 was as follows: A first hole-transport layer was formed as a film of Compound 2 (presented below) having a thickness of 90 nm, then a second hole-transport layer was formed as a film of Compound 3 (presented below) having a thickness of 10 nm, then Compounds 4 and 5 (presented below) were co-deposited by vapor deposition with the deposition speed set at 0.98 Å/s and 0.02 Å/s, respectively, to provide a light-emitting layer having a thickness of 35 nm, and finally an electron-transport layer was formed by vapor deposition as a film of Compound 1 (presented above) having a thickness of 60 nm.

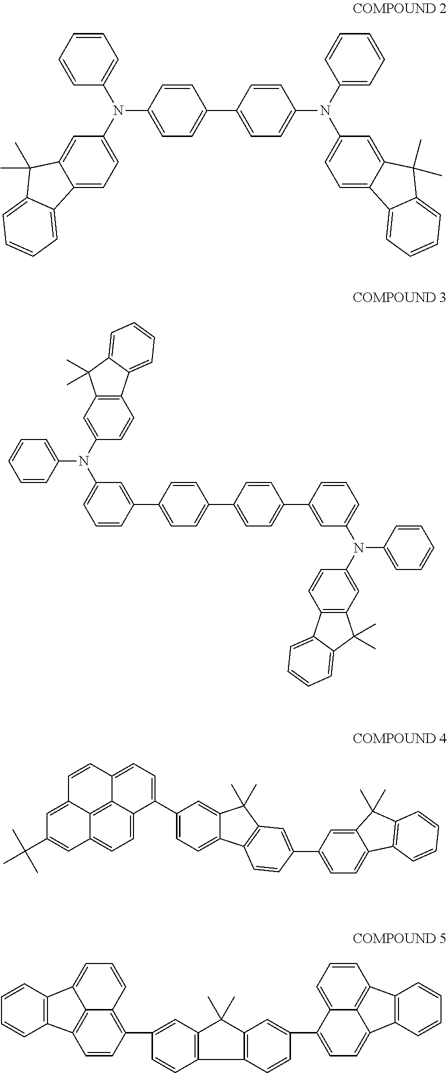

Then, as a component of a second electrode 15, a base layer 13 was formed as a Li₂O—Mg hybrid film under the following conditions: deposition speed of Li₂O; 0.7 Å/s: deposition speed of magnesium: 0.3 Å/s; target thickness: 4.0 nm. As can be determined from the deposition speeds specified above, the content ratio of magnesium in the base layer 13 was 30% by volume. Then, as the other component of the second electrode 15, a metal layer 14 was formed as a silver thin film having a thickness of 10 nm with the film formation speed set at 0.3 Å/s.

The obtained structure was placed in a glove box filled with nitrogen and then covered with a sheet of glass containing a desiccating agent and sealed using an epoxy resin adhesive agent.

The obtained organic EL element was subjected to the measurement of current efficiency. When the current density was set at 10 mA/cm², the voltage applied was 4.1 V and the current efficiency measured was 5.2 cd/A, demonstrating that this organic EL element according to Example 1 of the present invention could be operated even at a low voltage and offered a high luminous efficiency.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-045541 filed Mar. 2, 2010 and 2011-013277 filed Jan. 25, 2011, which are hereby incorporated by reference herein in their entirety.

What is claimed is:

1. An organic electroluminescence (EL) element comprising:
a substrate;
a first electrode;
a second electrode; and
an organic compound layer, wherein:
the organic compound layer is placed between the first electrode and the second electrode and contains a light-emitting layer;
the second electrode has a base layer and a metal layer formed on this base layer, and light generated in the organic EL element is transmitted through the second electrode;
the base layer is closer to the substrate than the metal layer and is a mixed layer containing lithium, oxygen, and magnesium; and
the metal layer contains silver and has a thickness in the range of 5.0 to 20 nm, inclusive.

2. The organic EL element according to claim 1, wherein:
the content ratio of magnesium in the base layer is in the range of 10% to 50% by volume, inclusive.

3. The organic EL element according to claim 1, wherein:
the content ratio of magnesium in the base layer is in the range of 10% to 30% by volume, inclusive.

4. The organic EL element according to claim 1, wherein:
the content ratio of magnesium in the base layer is in the range of 8.8% to 46.3% by weight, inclusive.

5. The organic EL element according to claim 1, wherein:
the content ratio of magnesium in the base layer is in the range of 8.8% to 27.0% by weight, inclusive.

6. The organic EL element according to claim 1, wherein:
the content ratio of magnesium in the base layer is in the range of 10.6% to 51.5% by number of moles, inclusive.

7. The organic EL element according to claim 1, wherein:
the content ratio of magnesium in the base layer is in the range of 10.6% to 31.3% by number of moles, inclusive.

8. The organic EL element according to claim 1, wherein:
the base layer has a thickness in the range of 4.0 to 16 nm, inclusive.

9. The organic EL element according to claim 1, wherein:
the base layer has a thickness in the range of 6.0 to 10 nm, inclusive.

10. A light-emitting apparatus comprising:
a plurality of pixels each provided with an organic EL element and
a mechanism for controlling the intensity of light emitted from the pixels, wherein:
some or all of the pixels are provided with the organic EL element according to claim 1.

11. The light-emitting apparatus according to claim 10, wherein:
the pixels include a red pixel, a green pixel, and a blue pixel.
